(19) United States
(12) Patent Application Publication
(10) Pub. No.: US 2002/0140055 A1
(43) Pub. Date: Oct. 3, 2002

(54) Photocell for high speed and pulsed light designs

(76) Inventor: Brian J. Misek, Collins, CO (US)

Correspondence Address: AGILENT TECHNOLOGIES, INC., Legal Department, 51U-PD, Intellectual Property Administration, P. O. Box 58043, Santa Clara, CA, 95052-8043, US

(21) Appl. No.: 09/821,735

(22) Filed: Mar. 28, 2001

(51) Int. Cl. H01L 27/082; H01L 27/102; H01L 29/70; H01L 31/11

(52) U.S. Cl. 257/593

(57) ABSTRACT

A photocell includes an emitter having a ratio of salicided area to non-salicided area. The ratio determines the gain of the photocell and lowers fixed pattern noise.

### FIELD OF THE INVENTION

The invention is directed towards the field of high speed and pulsed light applications, more particularly towards improving the energy efficiency of such applications.

### BACKGROUND

FIG. 1 illustrates a prior art photocell circuit schematic diagram that has been described in U.S. Pat. No. 6,037,643 “Photocell layout for high-speed optical navigation microchips” and U.S. Pat. No. 5,769,384 “Low differential light level photoreceptors”, assigned to the Hewlett-Packard Company and Agilent Technologies. The light signal is converted in the base of the transistor to electrons and multiplied by the current gain of the transistor to form the discharging current pulled from the integration capacitor. FIG. 2 illustrates a prior art layout design associated with the circuit schematic diagram shown in FIG. 1. This design has a large emitter area that results in a slow, e.g. 2 milliseconds, response to pulsed light operation. As applications migrate from low light to high light level-shift applications, e.g. pulsed light emitting device (LED) designs in optical navigation devices, the response time of these sensors is too slow.

As shown in FIG. 2, the emitter diffusion is the inner-cross area that wraps around the photocell. This emitter diffusion has two-reversed bias diode junction capacitances, one associated with the emitter area and the other with the emitter perimeter. These reversed bias capacitances need to be minimized in a pulsed application and the only way to accomplish this is to reduce the area and perimeter components as the reversed bias depletion thickness is fixed for a given doping profile. As the signal changes, e.g. pulse light applications, the photocell attempts to rebias the capacitor at a different voltage value to match the current that flows through it. When an impulse occurs, there is a lag and roll-off due to the re-biasing. The photocell response corresponds to a low pass filter roll-off.

### SUMMARY

A photocell includes a collector having a first polarity, a base having a second polarity, and an emitter having the first polarity. The emitter includes salicided and non-salicided areas. The ratio of the areas is at least 8:1. The non-salicided area is centered within the third region. The non-salicided area preferably has a shape having an area to perimeter ratio of that ranges from 8:1 to 24:1. This shape may be selected from a group that includes squares, crosses, and tori.

### BRIEF DESCRIPTION OF THE DRAWINGS

FIG. 1 illustrates a circuit schematic diagram according to the prior art.

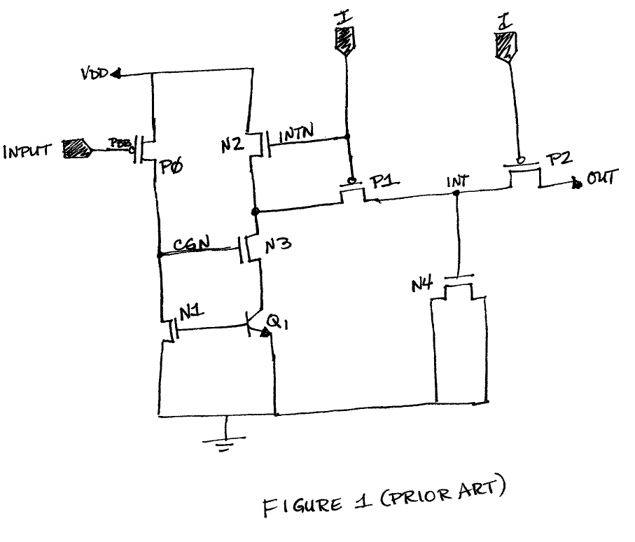

FIG. 2 illustrates a prior art layout associated with FIG. 1.

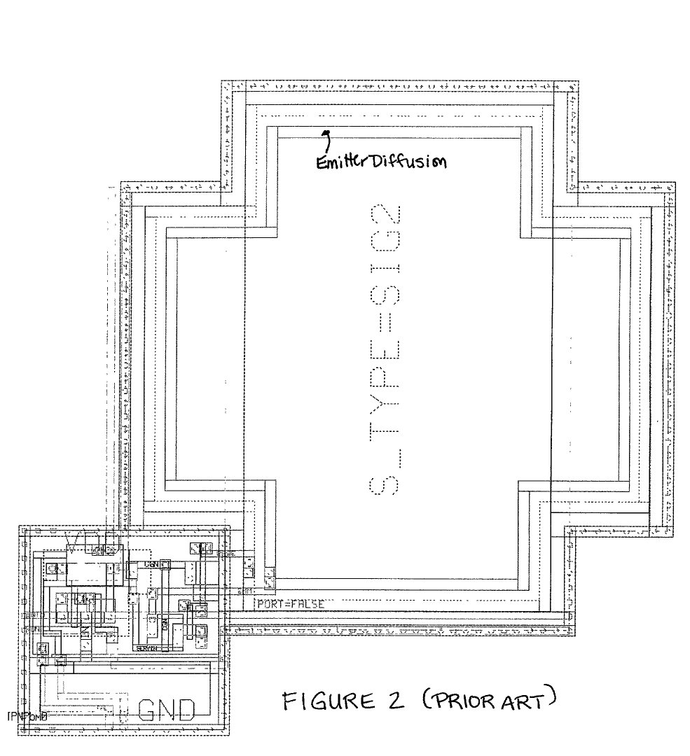

FIG. 3 illustrates an embodiment of the present invention.

FIG. 4 illustrates an alternate embodiment of the present invention.

### DETAILED DESCRIPTION

It is desirable to reduce the emitter-to-base parasitic capacitance that must be charged and discharged to bias the transistor at the signal current level developed by the incident light power. The only source of charge to rebias this capacitance is the very signal current that the circuit would integrate onto the integration capacitor. This represents a loss of information at high frequencies for continuous light operation and a total loss of signal, during rebiasing periods, for pulsed light operations.

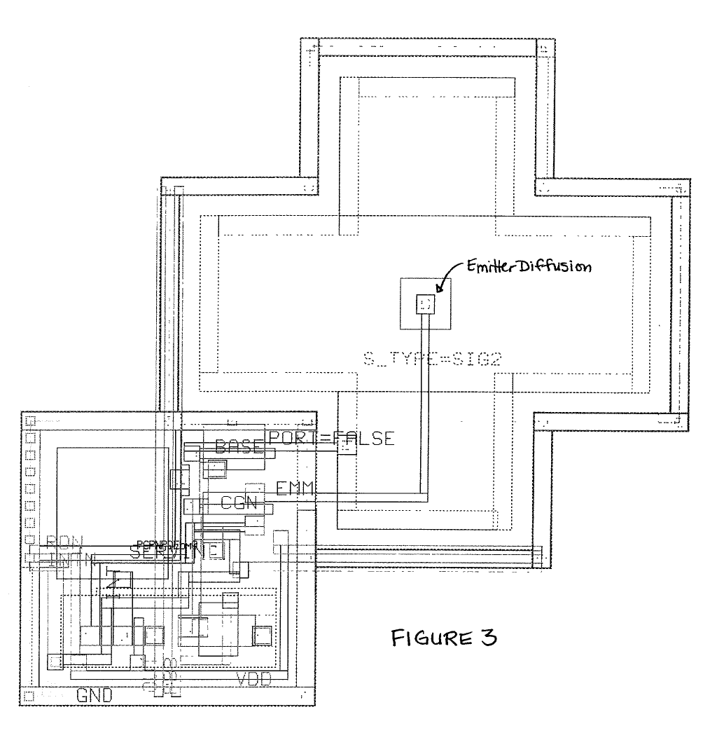

In the present invention, the emitter is placed in a different physical configuration than that illustrated in the prior art. The emitter is small and placed preferably in the geometric center of the pixel. The emitter preferably has the shape of a small square as opposed to the ring approach of the prior art. FIG. 3 illustrates an embodiment of the present invention. The salicided to non-salicided ratio of the dot emitter is selected to minimize the gain or beta suppression. It is preferably that the ratio of the salicided area to the unsalicided area exceeds 8:1. The unsalicided area preferably has a closed shape having an area to perimeter ratio of that ranges from 8:1 to 24:1.5. The closed shape may be a squares, cross, or torus.

The highest beta possible for the operating current levels will optimize the performance or speed of the sensor. The minimum salicided area for contacting the emitter diffusion is process dependent. The non-salicided area is added to the emitter to mitigate the beta suppression at the higher current densities in accordance with the application.

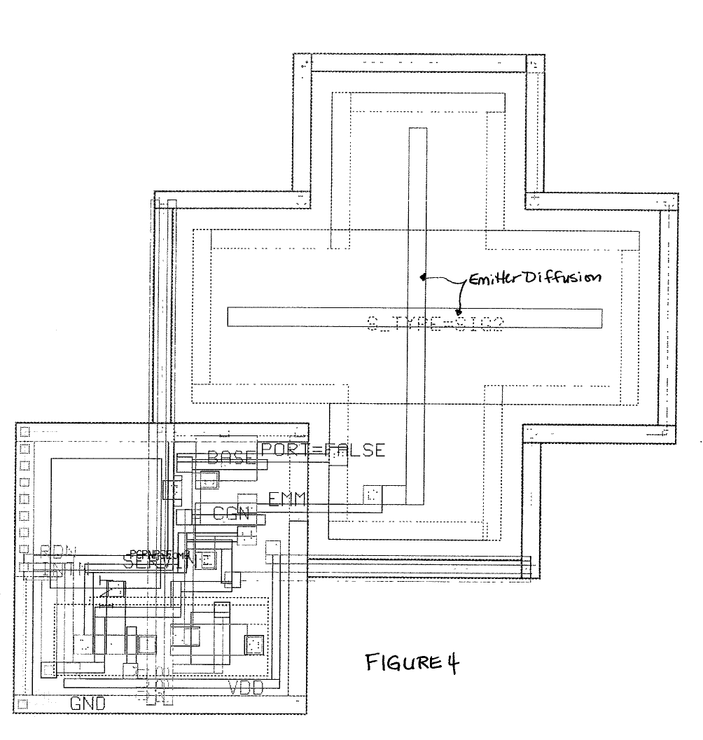

FIG. 4 illustrates an alternate embodiment of the present invention. The non-salicided area is shaped as a “cross” structure. This embodiment is suitable for applications that need higher beta at “high” current levels. The use or more non-salicided emitter diffusion increases the high current beta at the expense of decreased response time due to the additional emitter-to-base capacitance.

While the illustrated embodiments describe a PNP transistor in a n-well CMOS process, this could be a NPN transistor in a p-well CMOS process. Twin well process allows either design to be used. The invention can be easily extended to fabrication processes where the base node of a transistor is a high impedance voltage source, e.g. bi-CMOS process.

While the preferred embodiment places the small dot emitter in the geometric center of the pixel, the dot emitter can be placed any where in the base region. Alternate placement will have slight effects on the base resistance but will not significantly differ in operation. An advantage of placing the dot closer to one side is that the routing to connect the emitter to the control circuitry is reduced. This routing blocks light and as such prevents some light signal from reaching the detector.

I claim:

1. A photocell comprising:
a first region having a first polarity;
a second region having a second polarity, adjacent the first region; and
a third region having the first polarity, adjacent the second region, having a first area that includes salicide and a second area.

2. A photocell, as defined in claim 1, wherein the second area is centered within the third region.

3. A photocell, as defined in claim 2, wherein the ratio of the first area to the second area exceeds 8:1.

4. A photocell, as defined in claim 1, wherein the second area has a closed shape having an area to perimeter ratio of that ranges from 8:1 to 24:1.

5. A photocell, as defined in claim 4, wherein the second area has a shape selected from a group that includes squares, crosses, and tori.

6. A photocell comprising:
a collector having a first polarity;
a base having a second polarity, adjacent the collector;
an emitter having the first polarity, adjacent the base, having a first area that includes salicide and a second area.

7. A photocell, as defined in claim 6, wherein the second area is centered within the emitter.

8. A photocell, as defined in claim 7, wherein the ratio of the first area to the second area exceeds 8:1.

9. A photocell, as defined in claim 6, wherein the second area has a closed shape having an area to perimeter ratio of that ranges from 8:1 to 24:1.

10. A photocell, as defined in claim 9, wherein the second area has a shape selected from a group that includes squares, crosses, and tori.
